(19) United States
(12) Patent Application Publication
(10) Pub. No.: US 2013/0255762 A1
(43) Pub. Date: Oct. 3, 2013

(54) PASSIVATION LAYER FOR SOLAR CELLS AND METHOD FOR MANUFACTURING THE SAME

(71) Applicants: ETERNAL CHEMICAL CO., LTD., Kaohsiung (TW); NEW E MATERIALS CO., LTD., Kaohsiung City (TW)

(72) Inventors: FU-CHUAN FANG, KAOHSIUNG (TW); JIA-HONG CHEN, KAOHSIUNG (TW); JUI-YI HUNG, KAOHSIUNG (TW); CHING-CHANG WEN, Kaohsiung City (TW)

(73) Assignees: NEW E MATERIALS CO., LTD., Kaohsiung City (TW); ETERNAL CHEMICAL CO., LTD., KAOHSIUNG (TW)

(21) Appl. No.: 13/764,821

(22) Filed: Feb. 12, 2013

(30) Foreign Application Priority Data
Mar. 30, 2012 (TW) 101111642

(51) Int. Cl. H01L 31/0216

(52) U.S. Cl. CPC H01L 31/02167
USPC 136/256; 438/57

(57) ABSTRACT

The present invention pertains to a passivation layer disposed on a surface of a substrate for use in solar cells, including a first passivation layer formed on the substrate by screen printing. The present invention also pertains to a method for preparing the passivation layer structure. The method according to the present invention can prepare a passivation layer on a surface of a semiconductor substrate by screen printing, and during the screen printing, a patterning step can be performed simultaneously. Therefore, the present invention is able to produce the passivation layer in a more economic and faster manner.

### FIELD OF THE INVENTION

The present invention relates to a passivation layer capable of improving the photoelectric conversion efficiency of a solar cell, and a method for manufacturing the passivation layer, and in particular, to an alumina passivation layer in solar cells and a method for manufacturing the alumina passivation layer.

### DESCRIPTION OF THE RELATED ART

Global advances in science, technology and economic prosperity have imposed greater demands on energy sources. Declining reserves of raw materials such as petroleum, natural gas and coal have fueled vigorous pursuit of alternative energy sources. Advantages in terms of lack of pollution and ease of acquisition, have made solar energy one of the most attractive and important alternative energy sources.

FIG. 1 is a schematic view of a conventional solar cell, where an n-type doped layer 2 is formed on a p-type silicon semiconductor substrate 1 by doping, and then an anti-reflective layer 3 (such as silicon nitride) and an electrode 4 are formed on the n-type doped layer 2, and a back electrode 5 is formed on the other side of the p-type silicon semiconductor substrate 1. In this structure, the silicon semiconductor substrate 1 and the doped layer 2 can conduct in various manners, that is, a combination of the n-type silicon semiconductor substrate and the p-type doped layer can be selected. An internal electric field is formed between the p-type silicon semiconductor substrate 1 and the n-type doped layer 2. When light is irradiated on the silicon substrate, electrons of silicon atoms are excited to generate light-generated electron-hole pairs. Under the effect of an electric field on the electron-hole pairs, the positive and negative charges in the cell converge at electrodes at two ends, respectively. At this time, when a circuit is applied externally to connect the electrodes, electric power in the cell is available.

However, the electron-hole pairs are not available due to recombination in the solar cell, resulting in lowered photoelectric conversion efficiency of the solar cell. To reduce recombination of the electron-hole pairs, it is known that a negatively charged passivation layer (such as alumina layer) may be formed between the back electrode 5 and the p-type silicon semiconductor substrate 1, to restrain the direction of movement of minority carriers and prevent the electrons from moving towards the back electrode 5, thereby reducing the probability of recombination of the electron-hole pairs and prolonging life time of the minority carriers, so as to improve photoelectric conversion efficiency. Such a phenomenon is referred to as a back surface field effect.

The alumina passivation layer may be fabricated by using a dry process (as disclosed in US Patent Publication No. 2009165855 and China Patent Publication No. 101330114) or a wet process. The dry process includes atomic layer deposition (ALD), chemical vapor deposition (CVD), sputtering and the like. The alumina passivation layer needs to grow in a high vacuum, and the dry process has the disadvantages of extremely slow growth and high cost. The wet process or the dry process, nevertheless, requires disadvantageously complex processing in subsequent application. For example, patterning treatment (contact hole (via) opening) needs to be performed on the alumina passivation layer to fabricate a local contact. In a conventional patterning (contact hole (via) opening) process, lithographic etching is mainly used; such a conventional process includes at least five main steps, namely, photoresist coating, exposing, developing, etching and stripping. Next, in order to simplify the process, patterning is carried out by laser. The film material is directly stripped by the laser-patterning technology, enabling high-solution patterns to be fabricated on the substrate. Although equipment cost is reduced and process efficiency improved compared with the conventional patterning process, an additional process is required to complete the patterning treatment, thus lowering rate of production.

Therefore, there is still a need at present for a method for fabricating an alumina passivation layer in solar cells in a rapid, high-throughput and inexpensive treatment manner where direct patterning (contact hole (via) opening) can be adopted.

### BRIEF SUMMARY OF THE INVENTION

The present invention provides a passivation layer in a solar cell manufactured by a simple process, to improve the surface passivation effect, so as to improve the photoelectric conversion effect of the solar cell.

### BRIEF DESCRIPTION OF THE DRAWINGS

The invention will be described according to the appended drawings in which:

FIG. 1 is a typical structural view of a conventional solar cell;

FIG. 2 is a patterned image; and

FIG. 3 is a schematic view of a passivation layer fabricated by a method according to the present invention.

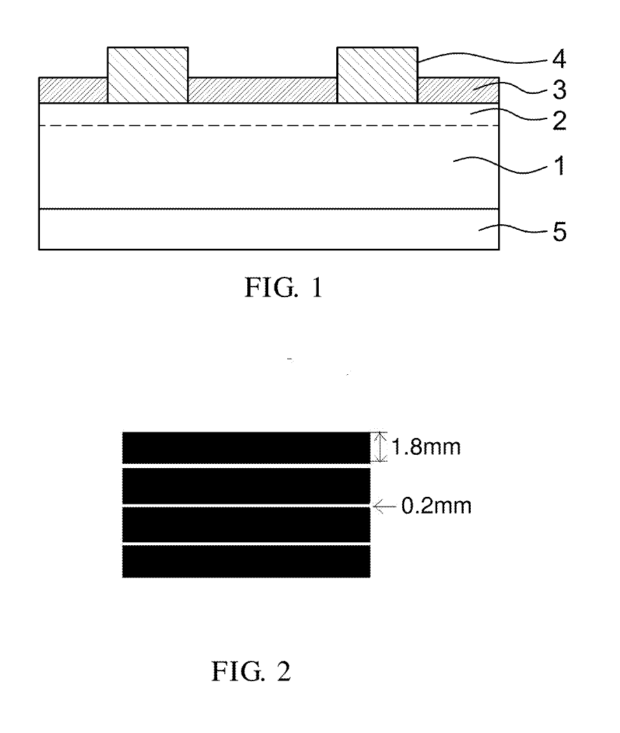

### DETAILED DESCRIPTION OF THE INVENTION

In view of this, the present invention is directed to a passivation layer disposed on a surface of a substrate in the solar cell, including a first passivation layer formed on the substrate by screen printing.

The present invention is further directed to a method for fabricating a passivation layer in a solar cell, which includes: providing a substrate; and forming a first passivation layer on a surface of the substrate by screen printing.

The screen printing has already been a well-established and widely-used technology; however, according to the prior art, the screen printing cannot be applied in fabrication of a passivation layer in a solar cell in the field of the present invention. The present invention provides a method for fabricating a passivation layer on a substrate by screen printing, and specifically, a method for fabricating a passivation layer on a semiconductor substrate by screen printing, where a patterning step is carried out simultaneously during screen printing. Compared with the processes used in the prior art, for example, the atomic layer deposition (ALD), chemical vapor deposition (CVD) and sputtering, the screen printing process according to the present invention has the advantages of low cost, rapid production and being capable of being patterned.

In the following, some implementation aspects according to the present invention will be described in detail; however, without departing from the spirit of the present invention, the present invention can be implemented by aspects in many different manners, and the protection scope of the present invention should not be construed to be limited to those described in the specification. Moreover, in the accompanying drawings, for clear illustration, objects and regions may be exaggerated in size, but not shown with the actual proportion. In addition, unless otherwise indicated herein, terms “a/an”, “the” and the like used in the specification (particularly, the following claims) should be construed as including the singular and the plural forms.

The present invention provides a passivation layer disposed on a surface of a substrate in a solar cell, including a first passivation layer formed on the surface of the substrate by screen printing.

Optionally, the passivation layer according to the present invention may include a second passivation layer disposed between the substrate and the first passivation layer.

The substrate is a substrate that is well known by those of ordinary skill in the art of the present invention, such as a semiconductor substrate (for example, a mono-silicon wafer, a poly-silicon wafer, film silicon, and amorphous silicon), an organic substrate, an inorganic compound semiconductor substrate (for example, a Group III-V, Group II-VI, or Group I-III-VI inorganic compound semiconductor substrate), a glass substrate and a metal substrate. The semiconductor substrate is, for example, a p-type silicon semiconductor substrate containing an n-type doped layer, or an n-type silicon semiconductor substrate containing a p-type doped layer.

According to the present invention, the first passivation layer generally has a thickness of at least 10 nm, and for avoiding burn-through in the process of fabricating an aluminum electrode, preferably has a thickness of about 20 nm to 2000 nm, and more preferably about 40 nm to 500 nm.

As the material of the first passivation layer according to the present invention, a metal oxide with negative fixed charge, for example, but not limited to, alumina, zinc oxide or indium tin oxide, may be used. According to an implementation aspect of the present invention, the first passivation layer of the present invention is an alumina (Al₂O₃) passivation layer formed by screen printing.

For forming a bond with a dangling bond on the silicon surface or at a defect (such as dislocation, grain boundary and point defect) and effectively reducing the recombination rate of electron-hole pairs on the silicon surface and at defects, so as to improve the life time of the minority carriers and improve the efficiency of the solar cell, optionally, the passivation layer in a solar cell according to the present invention may include a second passivation layer between the substrate and the first passivation layer. Generally, the second passivation layer may be formed by a thermal oxidization process, and has thickness of about 1 nm to 15 nm. According to an implementation aspect of the present invention, silicon oxide (SiO2) is used as the second passivation layer.

In the prior art, the first passivation layer is mostly formed by using a dry processes such as atomic layer deposition (ALD), chemical vapor deposition (CVD) and sputtering; however, the first passivation layer needs to grow in a high vacuum circumstance, and the dry process has the disadvantages of low process rate and high cost. In addition, the screen printing technology has strict requirements on the viscosity and fluidity of a coating composition (printing ink). After extensive researches, the inventor of the present invention finds that, if the coating composition that is used has a viscosity of at least 200 cps (centipoise) and high stability of viscidity, the coating composition may be applied on a substrate by screen printing to form a coating with good film-forming capability. In the present invention, the screen printing may be used directly to form the first passivation layer having a predetermined pattern (contact hole (via) opening) (as in FIG. 2), merely through thermal treatment (such as heating and sintering the coating) to form a first passivation layer having the predetermined pattern on the substrate, without additional photoresist exposure, development, etching or laser for patterning. Therefore, the method according to the present invention can significantly increase the growth rate of the first passivation layer and reduce the manufacturing cost of the process.

The present invention further provides a method for fabricating a passivation layer in a solar cell, including: providing a substrate; and forming a first passivation layer on a surface of the substrate by screen printing, where the substrate and the first passivation layer are as defined as above.

The screen printing includes the following steps:

a) providing a coating composition, where the coating composition has the viscosity of at least 200 cps (centipoise);

b) applying the coating composition on the substrate by screen printing, and forming a coating having a predetermined pattern; and

c) heating and sintering the coating to form a first passivation layer having the predetermined pattern on the substrate.

The coating composition in Step (a) contains a metal oxide precursor, a solvent and a thickening agent. The metal oxide is, for example, but is not limited to, alumina, zinc oxide or indium tin oxide.

The surface of the substrate in Step (b) refers to an upper surface or under surface of the substrate or both, and the substrate is a semiconductor substrate.

The sintering temperature in Step (c) is such a temperature that the sintering effect is achieved without damaging the substrate, and is generally about 300° C. to about 1000° C.

The content of the metal oxide precursor in the coating composition according to the present invention is about 1 to about 50 parts by weight, and preferably about 4 to about 23 parts by weight, based on 100 parts by weight of the coating composition as a whole.

According to a preferred implementation aspect of the present invention, the metal oxide precursor is an alumina precursor, which is sintered to form an alumina passivation layer as the first passivation layer. Therefore, according to a preferred implementation aspect of the present invention, the first passivation layer of the present invention is an alumina (Al₂O₃) passivation layer formed by screen printing. The screen printing includes the following steps:

I) providing a coating composition, where the coating composition has the viscosity of at least 200 cps (centipoise);

II) applying the coating composition on a surface of the substrate by screen printing, and forming a coating having a predetermined pattern; and

III) heating and sintering the coating, to form a first passivation layer having the predetermined pattern on the surface of the substrate.

The coating composition in Step (I) contains an alumina precursor, a solvent and a thickening agent. The content of the alumina precursor is about 1 to about 50 parts by weight, and preferably about 4 to about 23 parts by weight, based on 100 parts by weight of the coating composition as a whole.

The surface of the substrate in Step (II) refers to an upper surface or under surface of the substrate or both, and the substrate is a semiconductor substrate.

The sintering temperature in Step (III) is such a temperature that the sintering effect is achieved without damaging the substrate, and is generally about 300° C. to about 1000° C.

According to the present invention, the method for preparing the coating composition is not particularly limited, and includes: initially preparing an alumina precursor by a sol-gel process; after completing the reaction, optionally adjusting the resulting solution to a desired pH with an appropriate amount of water and a base or acid (such as nitric acid); and adding the solvent and thickening agent and homogeneously stirring, to prepare the coating composition according to the present invention.

To provide a desirable back surface field effect, the first passivation layer in the method according to the present invention contains amorphous alumina particles having a mean particle size of about 1 nm to about 30 nm and preferably about 5 nm to about 20 nm, and the alumina layer has generally a thickness of about 10 nm to about 2000 nm.

To make the alumina precursor stably present in the solvent, the alumina precursor in the method according to the present invention is formed by reaction of a bidentate chelating agent with an alumina derivative at a mole ratio of about 0.3 to 3, and preferably 1 to 3 for keeping stability of viscidity of the coating composition in a long time and enhancing the film-forming capability of the passivation layer obtained after the alumina precursor composition is sintered. The alumina derivative may be represented by a general formula Al(OR₁)₃, where R₁ is H or a substituted or unsubstituted C1-C13 alkyl, and preferably H, methyl, ethyl, propyl or butyl. The bidentate chelating agent is preferably

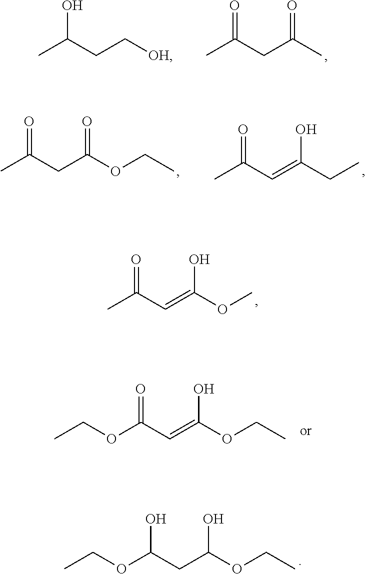

The method for preparing the alumina precursor is not particularly limited, and may be, for example, but is not limited to, a sol-gel process. For example, if the chelating agent butan-1,3-diol is selected to prepare the alumina precursor, the preparation method includes intensively mixing the alumina derivative of general formula Al(OR₁)₃ with butan-1,3-diol to give the desired alumina precursor (the mole ratio of about 0.3 to 3, for example 1:1):

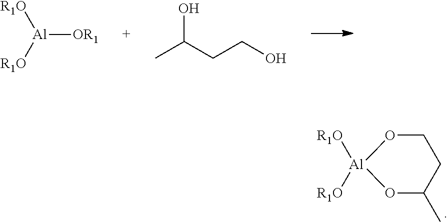

According to an implementation aspect of the present invention, the alumina precursor contains one or more compounds having the structures below:

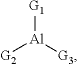

where G₁, G₂ and G₃ may be the same or different, and are each independently OR₁ or a bidentate chelating group, where R₁ is as defined as above, and the bidentate chelating group is preferably

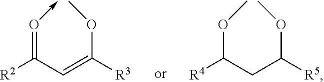

where R² and R³ may be the same or different, R⁴ and R⁵ may be the same or different, and R², R³, R⁴ and R⁵ are each independently H or a substituted or un-substituted C1-C10 alkyl or alkoxy, and preferably methyl, ethyl, methoxy, ethoxy. In some implementation aspects of the present invention, the bidentate chelating group is selected from the group consisting of:

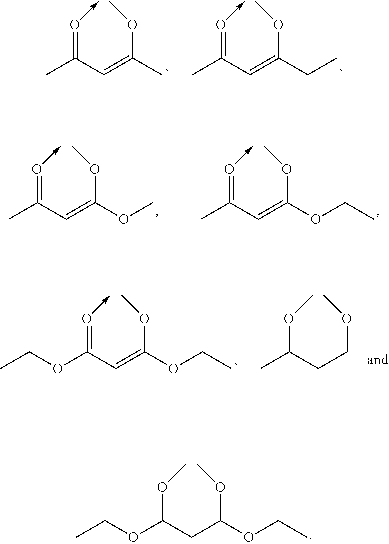

The solvent useful in the coating composition according to the present invention may be any inert solvent that can dissolve or homogeneously disperse the alumina precursor and does not react with the alumina precursor, and may be selected from water, alcohols, ethers, esters, ether alcohols, ketones or a combination thereof, and preferably water, alcohols, ethers or a combination thereof, and most preferably alcohol solvents.

The screen printing technology has strict requirements on the viscosity and fluidity of the coating composition (printing ink), and for obtaining a coating composition having a viscosity of at least 200 cps, according to the present invention, a thickening agent may be used to adjust the viscosity of the coating composition to be in the range of desired values, which is generally determined according to the mesh number of a screen used in screen printing. According to an implementation aspect of the present invention, the screen used in screen printing according to the present invention has a sizing grid of about 100 to 300 meshes, and preferably about 200 to 250 meshes, and the coating composition preferably has a viscosity of 1100 cps to 105600 cps, and most preferably 2500 cps to 75000 cps.

For example, the thickening agent useful in the present invention may be selected from the group consisting of cellulose derivatives, acrylic polymers, silicon oxide, polyethylene glycol polymer and a mixture thereof. The cellulose derivatives are preferred in consideration of superior mechanical properties and storage stability of the coating composition. In some implementation aspects of the present invention, the thickening agent can be methyl cellulose, ethyl cellulose, hydroxyethyl cellulose, hydroxypropyl cellulose, hydroxypropylmethyl cellulose, or carboxymethyl cellulose or a mixture thereof. Based on 100 parts by weight of the coating composition as a whole, the content of the thickening agent used in the coating composition according to the present invention is about 1 to about 20 parts by weight, and preferably 2 to about 10 parts by weight in consideration of carbon residues generated after sintering.

Optionally, the method for fabricating a passivation layer in a solar cell according to the present invention includes forming a second passivation layer between the substrate and the first passivation layer. The second passivation layer is as defined as above. The present invention further provides a solar cell component, including a passivation layer formed by screen printing.

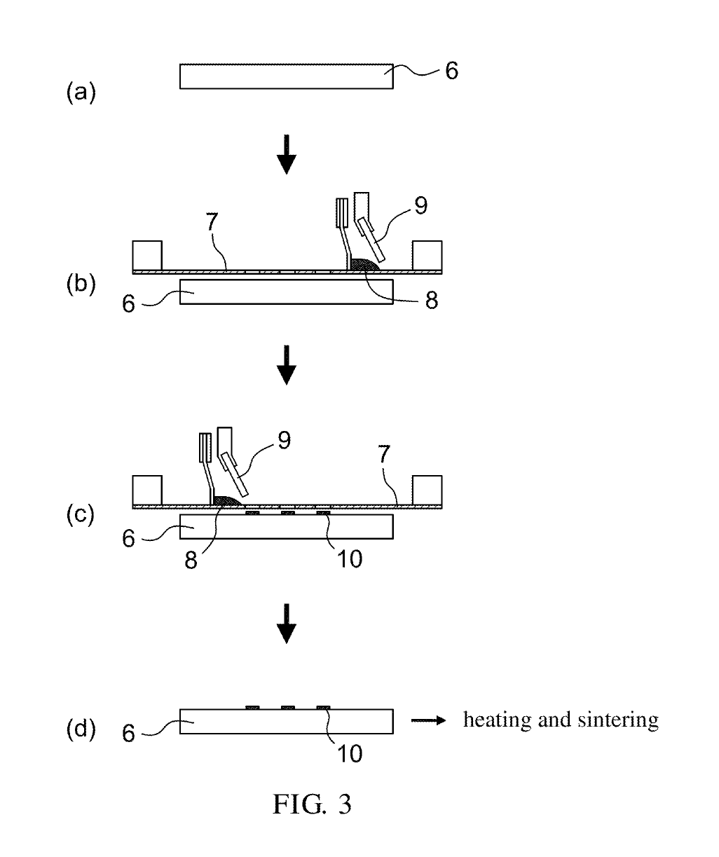

For further illustration of the present invention, a specific implementation aspect of the method for fabricating a passivation layer according to the present invention will be exemplified in reference to FIG. 3 (Steps (a) to (d)), which is only for illustration, but not intend to limit the protection scope of the present invention.

A substrate 6 (for example, a silicon semiconductor substrate including an n-type doped layer on a p-type silicon semiconductor) is provided, as shown in FIG. 3(a); a coating composition 8 having a viscosity of at least 200 cps is applied onto a substrate 6 by means of a knife 9 by screen printing (a screen 7 has about 100-300 meshes), as shown in FIG. 3(b); a coating 10 having a predetermined pattern is formed, as shown in FIG. 3(c); and the coating 10 is sintered in a sintering furnace, as shown in FIG. 3(d), to form a first passivation layer (having a thickness of about 40 nm to 500 nm) having the predetermined pattern on the substrate.

### EXAMPLES

The present invention is further described in the following embodiments, and the measuring instrument and method used are as follows, which are not intended to limit the scope of the present invention, modifications and variations made by those skilled in the art without departing from the spirit of the present invention fall within the scope of the present invention.

### Viscosity Test

According to the ASTM D4287-94 standard method, the viscosity of the coating composition is measured at 25° C. at a rotation speed of 0.6 rpm by using a Brookfield HB viscosimeter, in combination with a CP51 rotating disk.

### Preparation of Passivation Layer Material

### Example 1

A coating composition (5% alumina precursor

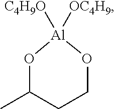

4% ethyl cellulose, viscosity of 5000 cps) dissolved in sec-butyl alcohol was applied onto a p-type silicon wafer having a thickness of 180 μm by a screen printer ASYS EKRAII (the screen of 200 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Example 2

A coating composition (8% alumina precursor

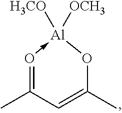

6% hydroxyethyl cellulose, viscosity of 40000 cps) dissolved in sec-butyl alcohol was applied onto a p-type silicon wafer having a thickness of 180 μm by a screen printer ASYS EKRAII (the screen of 200 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Example 3

A coating composition (12% alumina precursor

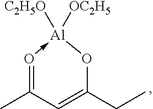

7% hydroxypropyl cellulose, viscosity of 70000 cps) dissolved in sec-butyl alcohol was applied onto a p-type silicon wafer having a thickness of 180 μm by a screen printer ASYS EKRAII (the screen of 200 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Example 4

A coating composition (15% alumina precursor

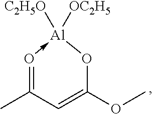

6% methyl cellulose, viscosity of 74000 cps) dissolved in sec-butyl alcohol was applied onto a p-type silicon wafer having a thickness of 180 μm by a screen printer ASYS EKRAII (the screen of 200 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Example 5

A coating composition (20% alumina precursor

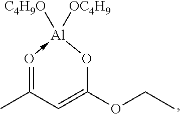

6% hydroxypropylmethyl cellulose, viscosity of 22000 cps) dissolved in sec-butyl alcohol was applied onto a p-type silicon wafer having a thickness of 180 μm by a screen printer ASYS EKRAII (the screen of 200 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Example 6

A coating composition (23% alumina precursor

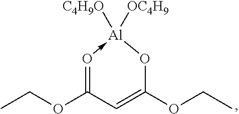

5% carboxymethyl cellulose, viscosity of 18400 cps) dissolved in sec-butyl alcohol was applied onto a p-type silicon wafer having a thickness of 180 μm by a screen printer ASYS EKRAII (the screen of 200 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Example 7

A coating composition (28% alumina precursor

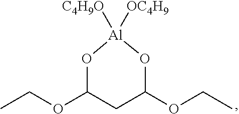

4% hydroxypropyl cellulose, viscosity of 3200 cps) dissolved in sec-butyl alcohol was applied onto a p-type silicon wafer having a thickness of 180 μm by a screen printer ASYS EKRAII (the screen of 200 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Example 8

A coating composition (39% alumina precursor

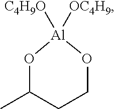

3% methyl cellulose, viscosity of 2700 cps) dissolved in sec-butyl alcohol was applied onto a p-type silicon wafer having a thickness of 180 μm by a screen printer ASYS EKRAII (the screen of 200 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Example 9

A coating composition (1.2% alumina precursor

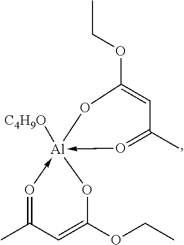

12% hydroxypropyl cellulose, viscosity of 15875 cps) dissolved in sec-butyl alcohol was applied onto a p-type silicon wafer having a thickness of 180 μm by a screen printer ASYS EKRAII (the screen of 250 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Example 10

A coating composition (3.5% alumina precursor

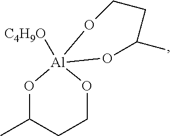

10% ethyl cellulose, viscosity of 17463 cps) dissolved in sec-butyl alcohol was applied onto a p-type silicon wafer having a thickness of 180 μm by a screen printer ASYS EKRAII (the screen of 250 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Example 11

A coating composition (6% alumina precursor

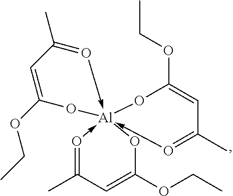

7% ethyl cellulose, viscosity of 11113 cps) dissolved in sec-butyl alcohol was applied onto a p-type silicon wafer having a thickness of 180 μm by a screen printer ASYS EKRAII (the screen of 250 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Example 12

A coating composition (7% alumina precursor

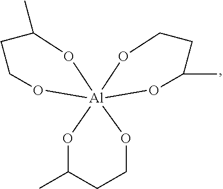

6% hydroxypropyl cellulose, viscosity of 19050 cps) dissolved in sec-butyl alcohol was applied onto a p-type silicon wafer having a thickness of 180 μm by a screen printer ASYS EKRAII (the screen of 250 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Example 13

A coating composition (11% alumina precursor

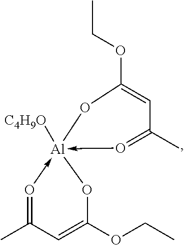

10% hydroxypropyl cellulose, viscosity of 17463 cps) dissolved in sec-butyl alcohol was applied onto a p-type silicon wafer having a thickness of 180 μm by a screen printer ASYS EKRAII (the screen of 250 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Comparative Example 1

A coating composition (6% alumina precursor

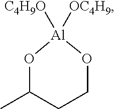

viscosity of 1 cps) dissolved in sec-butyl alcohol was applied onto a p-type silicon wafer having a thickness of 180 μm by a screen printer ASYS EKRAII (the screen of 200 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Comparative Example 2

A coating composition (8% alumina precursor

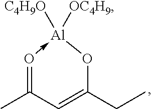

viscosity of 35 cps) dissolved in sec-butyl alcohol was applied onto a p-type silicon wafer having a thickness of 180 μm by a screen printer ASYS EKRAII (the screen of 200 meshes), to form a predetermined pattern. The wafer was dried in an infrared hot air dryer at a temperature in the range of 150° C. to 200° C. and sintered at a temperature in the range of 300° C. to 1000° C. to form an alumina passivation layer on the p-type silicon wafer surface, and then annealed at a mixing atmosphere of nitrogen and hydrogen to complete fabrication of the composite, and the film-forming capability and patterning capability of the alumina passivation layer in the composite were measured. The results were recorded in Table 1.

### Test of Film-Forming Capability of Passivation Layer Material

The criteria for film-forming capability are as follows: scratching the resulting alumina layer surface by a Bagger knife, then adhering the alumina layer surface with a tape and tearing the tape up at an angle perpendicular to the alumina layer, and observing the number of grids peeled in the alumina layer; if the number of remaining grids is greater than 90, the film-forming capability is rated as good and marked as “◯”; if the number of remaining grids is 70 to 90, the film-forming capability is rated as general and marked as “Δ”; and if the number of remaining grids is less than 70, the film-forming capability is rated as “poor” and marked as “×”.

### Patterning Capability Test

The criteria for patterning capability are as follows: with the screen in FIG. 2 as an example (without limitation), the screen printing is carried out at a line width of 0.2 mm and a line spacing of 1.8 mm as described in the embodiment, and detected at a site above the line, a site in the line and a site below the line by a crystalline phase microscope (model: Nikon MM400-Lu), the values are averaged. If the measured line width error is less than 5% of the average, the patterning capability is marked as “◯”; and if the measured line width error is greater than 5% of the average, the patterning capability is marked as “×”.

TABLE 1

| | | | film-forming | patterning |
|---|---|---|---|---|
| | meshes | viscosity | capability | capability |
| Example 1 | 200 | 5000 | ∘ | ∘ |
| Example 2 | 200 | 40000 | ∘ | ∘ |
| Example 3 | 200 | 70000 | ∘ | ∘ |
| Example 4 | 200 | 74000 | ∘ | ∘ |
| Example 5 | 200 | 22000 | ∘ | ∘ |
| Example 6 | 200 | 18400 | ∘ | ∘ |
| Example 7 | 200 | 3200 | ∘ | ∘ |
| Example 8 | 200 | 2700 | ∘ | ∘ |
| Example 9 | 250 | 15875 | ∘ | ∘ |
| Example 10 | 250 | 17463 | ∘ | ∘ |
| Example 11 | 250 | 11113 | ∘ | ∘ |
| Example 12 | 250 | 19050 | ∘ | ∘ |
| Example 13 | 250 | 17463 | ∘ | ∘ |
| Comparative | 200 | 1 | x | x |
| Example 1 | | | | |
| Comparative | 200 | 35 | x | x |
| Example 2 | | | | |

The life time of minority carriers of the poly-silicon wafers containing the passivation layer materials of Examples 1 to 13 was measured by using an instrument WCT-120 (universal mode) from Sinton Corporation. The results are recorded in Table 2.

Blank experiment: The p-type poly-silicon wafer uncoated with the coating composition was dried in an infrared hot air dryer at a temperature in the range of 150° C. to 200° C., and was sintered at a temperature in the range of 300° C. to 1000° C., and annealed at a mixing atmosphere of nitrogen and hydrogen, to provide a wafer for test. The life time of minority carriers was measured. The resulted are recorded in Table 2.

TABLE 2

| | life time of carriers(μs) |
|---|---|
| Example 1 | 27.40 |
| Example 2 | 27.09 |
| Example 3 | 28.40 |
| Example 4 | 31.10 |
| Example 5 | 21.59 |
| Example 6 | 29.92 |
| Example 7 | 23.28 |
| Example 8 | 22.88 |
| Example 9 | 18.17 |
| Example 10 | 31.10 |
| Example 11 | 39.00 |
| Example 12 | 24.83 |
| Example 13 | 20.57 |
| Blank | 4.95 |
| experiment | |

We claim:

1. A passivation layer disposed on a surface of a substrate in a solar cell, including a first passivation layer formed on the substrate by screen printing.

2. The passivation layer in a solar cell of claim 1, wherein the first passivation layer is a metal oxide with negative fixed charge.

3. The passivation layer in a solar cell of claim 1, wherein the first passivation layer is alumina, zinc oxide or indium tin oxide.

4. A method for fabricating a passivation layer in a solar cell, including: providing a substrate; and forming a first passivation layer on a surface of the substrate by screen printing.

5. The method of claim 4, wherein the screen printing includes the following steps:
a) providing a coating composition, where the coating composition has the viscosity of at least 200 cps (centipoise);
b) applying the coating composition on the substrate by screen printing, and forming a coating having a predetermined pattern; and
c) heating and sintering the coating to form a first passivation layer having the predetermined pattern on the substrate.

6. The method of claim 5, wherein the coating composition contains a metal oxide precursor, a solvent and a thickening agent.

7. The method of claim 6, wherein the coating composition contains an alumina precursor, a solvent and a thickening agent.

8. The method of claim 6, wherein thickening agent is selected from the group consisting of cellulose derivatives, acrylic polymers, silicon oxide, polyethylene glycol polymer and a mixture thereof.

9. The method of claim 4, wherein the screen used in screen printing has a sizing grid of about 100 to 300 meshes.
